(19) United States
(12) Patent Application Publication
(10) Pub. No.: US 2004/0164374 A1
(43) Pub. Date: Aug. 26, 2004

(54) Field effect transistor and method of manufacturing the same

(75) Inventor: Kouji Ishikura, Kanagawa (JP)

Correspondence Address: SUGHRUE MION, PLLC, 2100 PENNSYLVANIA AVENUE, N.W., SUITE 800, WASHINGTON, DC, 20037, US

(73) Assignee: NEC COMPOUND SEMICONDUCTOR DEVICES, LTD.

(21) Appl. No.: 10/778,199

(22) Filed: Feb. 17, 2004

(30) Foreign Application Priority Data
Feb. 20, 2003 (JP) 42512/2003

(51) Int. Cl. H01L 29/00

(52) U.S. Cl. 257/500

(57) ABSTRACT

A field effect transistor includes: a source electrode and a drain electrode formed above a semiconductor active layer; an insulating film formed between the source electrode and the drain electrode above the semiconductor active layer so as to have an opening in which its side wall on a drain electrode side includes a tapered portion formed so as to be inclined from a plane perpendicular to an upper surface of the semiconductor active layer toward the drain electrode; and a gate electrode contacted to the semiconductor active layer through the opening so as to cover at least the side wall on the drain electrode side. Thus, there is provided the field effect transistor which has high breakdown voltage and high linear gain characteristics.

### BACKGROUND OF THE INVENTION

1. Field of the Invention

The present invention relates to a field effect transistor and a method of manufacturing the same.

2. Description of the Prior Art

Among field effect transistors (FETs), a MES (Metal Semiconductor) FET has a gate electrode contacted to a semiconductor active layer (hereinafter referred to as “an active layer” for short when applicable) in which a depletion layer and a channel are generated. A voltage applied to the gate electrode controls a current between a source electrode and a drain electrode by changing a thickness of the depletion layer within the active layer. Among the MESEFTs, an FET having a compound semiconductor such as GaAs as an active layer, which has an electron mobility several times as large as that of a silicon semiconductor, is used for high frequency applications.

In the above-mentioned high frequency FET, a surface depletion layer is generated on a semiconductor surface between the gate electrode and the drain electrode. As a result, a gate lag problem is occurred in which the gate electrode becomes unable to control a depletion layer for a high frequency signal. Therefore, an output power becomes lower, thereby reducing efficiency, or a signal waveform is distorted. In particular, in a high breakdown voltage FET used for high output power applications, a distance between a gate electrode and a drain electrode is designed to be long. As a result, the surface depletion layer is easy to suffer from a bad influence due to roughness or contamination of the surface, and hence the above-mentioned problem is remarkable. In order to solve this problem, there was proposed an FP (Field-modulated Plate) FET designed so as to have a gate electrode provided with an FP (refer to JP 2000-100831 A).

FIG. 1 is a cross sectional view showing a structure of an example of a conventional FPFET. In the figure, a length Lfp of an FP provided in a gate electrode 150 is 1.0 μm, which is longer than that of a normal FET. Since the FP covers a part of a semiconductor surface, a concentration of an electric field generated in an active layer 12 underlying an insulating film 120 is relaxed to increase a breakdown voltage of the FPFET, and also a surface depletion layer is controlled to thereby suppress the occurrence of the gate lag.

However, the inventors of the present invention have found out a problem that in the above-mentioned FPFET, a parasitic capacity formed due to a structure in which the insulating film is sandwiched between the FP and the active layer is large, and hence the linear gain is low. Since the relaxation of the concentration of the electric field and the linear gain of the FPFET show a trade-off relationship, it was difficult to apply the FP to any of devices for which a high linear gain is severely required.

### SUMMARY OF THE INVENTION

It is, therefore, an object of the present invention to provide a field effect transistor which is capable of obtaining a high breakdown voltage and a high gain, and a method of manufacturing the same.

According to an aspect of the present invention, there is provided a field effect transistor, including: a drain electrode and a source electrode formed above a semiconductor active layer; an insulating film formed on the semiconductor active layer between the drain electrode and the source electrode; and a gate electrode formed in an opening of the insulating film formed between the drain electrode and the source electrode, in which a side wall of the opening of the insulating film through which the gate electrode touches the insulating film, on a side of the drain electrode, includes a tapered portion formed so as to be inclined from a plane perpendicular to an upper surface of the semiconductor active layer toward the drain electrode.

In the field effect transistor according to the present invention, since the gate electrode is formed so as to cover the tapered portion, an electric field which is concentrated on the gate edge during application of a voltage to the gate electrode is dispersed to a side of the drain electrode to relax the concentration of the electric field generated within the semiconductor active layer.

In addition, preferably, an angle of the tapered portion with the upper surface of the semiconductor active layer is made larger than 30 degrees, whereby it is possible to further suppress the reduction of a linear gain due to a parasitic capacity formed due to a structure in which the insulating film is sandwiched between the gate electrode and the semiconductor active layer. More preferably, an angle of the tapered portion with the upper surface of the semiconductor active layer is made smaller than 60 degrees, whereby the electric field concentrated on the gate edge during application of a voltage to the gate electrode is dispersed to the side of the drain electrode to further relax the concentration of the electric field generated in the semiconductor active layer.

According to another aspect of the present invention, there is provided a method of manufacturing a field effect transistor having a gate electrode between a drain electrode and a source electrode formed above a semiconductor active layer, including: forming an opening for exposure of a part of the semiconductor active layer in an insulating film formed between the drain electrode and the source electrode formed above the semiconductor active layer such that a side wall of the opening on a side of the drain electrode includes an tapered portion formed so as to be inclined from a plane perpendicular to an upper surface of the semiconductor active layer toward the drain electrode; and forming the gate electrode so as to cover at least the tapered portion and the upper surface of the semiconductor active layer in the opening.

In the field effect transistor according to the present invention, the opening is formed so that its side wall on the side of the drain electrode is provided with the inclination portion, and the gate electrode is formed so as to cover the inclination portion. As a result, an electric field concentrated on the gate edge during application of a voltage to the gate electrode is dispersed to the side of the drain electrode to relax the concentration of the electric field generated in the semiconductor active layer.

In addition, a photo resist film for formation of the opening is formed on the insulating film, and under the conditions of obtaining etching rates of the insulating film and the photo resist film allowing an angle of the tapered portion in the opening to fall within a range of 30 to 60 degrees, the insulating film is selectively etched away to form the opening, whereby it is possible to further suppress the reduction of a linear gain due to a parasitic capacity formed due to a structure in which the insulating film is sandwiched between the gate electrode and the semiconductor active layer, and the electric field concentrated on the gate edge during application of a voltage to the gate electrode can be dispersed to the side of the drain electrode to further relax the concentration of the electric field generated in the semiconductor active layer.

### BRIEF DESCRIPTION OF THE DRAWINGS

The above and other objects, advantages and features of the present invention will be more apparent from the following description taken in conjunction with the accompanying drawings, in which:

FIG. 1 is a schematic cross sectional view showing a structure of an example of a conventional FRFET;

FIG. 2 is a cross sectional view showing a structure of an FET according to a first embodiment of the present invention;

FIG. 3 is a schematic cross sectional view showing the structure of the FET of the first embodiment of the present invention and useful in explaining an intensity of an electric field;

FIG. 4 is a schematic cross sectional view showing an FET having a short FP in structure in a conventional FPFET and useful in explaining an intensity of an electric field;

FIG. 5 is a graphical representation useful in explaining comparison in breakdown voltage characteristics between conventional FPFETs and the FET of the first embodiment of the present invention;

FIG. 6 is a graphical representation useful in explaining comparison in RF characteristics between the conventional FPFETs and the FET of the first embodiment of the present invention;

FIGS. 7A to 7D are cross sectional views useful in explaining an example of a method of manufacturing the FET of the first embodiment of the present invention;

FIG. 8 is a cross sectional view showing a structure of an FET according to a second embodiment of the present invention; and

FIG. 9 is a graphical representation useful in explaining comparison in input/output characteristics between the FET of the first embodiment of the present invention and the FET of the second embodiment of the present invention.

### DETAILED DESCRIPTION OF THE PREFERRED EMBODIMENTS

First Embodiment

FIG. 2 is a cross sectional view showing a structure of an example of a field effect transistor (hereinafter referred to as “an FET” for short when applicable) according to a first embodiment of the present invention.

As shown in FIG. 2, in the FET of this embodiment, a gate electrode 50 is formed in a recess portion as a hollow portion on a surface of an active layer 12 formed on a part of a semiconductor substrate 10 between a source electrode 30 and a drain electrode 40 so as to be contacted to the active layer 12 to form a Schottky junction with the active layer 12 through an opening formed in an insulating film 20 overlying the active layer 12. The opening of the insulating film 20 has a cup-like shape having a tapered portion 20a which is formed so that a side wall of the opening on a side of the drain electrode 40 is inclined from a plane perpendicular to an upper surface of the active layer 12 to the side of the drain electrode 40, and a tapered portion 20b which is formed so that a side wall of the opening on a side of the source electrode 30 is inclined from the plane perpendicular to the upper surface of the active layer 12 toward the source electrode 30. In this embodiment, both the tapered portions 20a and 20b are covered with the gate electrode 50.

The gate electrode 50 is structured so as to have the Schottky metal layer 52 contacting the insulating film 20 and a part of the active layer 12 corresponding in position to the opening, and a gate metal layer 54 formed so as to overlie the Schottky metal layer 52. The gate electrode 50 is formed so that its length on the source electrode 30 side is longer than that on the drain electrode 40 side. Apart of the gate electrode 50 extending from the Schottky junction end on the drain electrode 40 side to the gate electrode end corresponds to an FP portion. Note that, since the FET of this embodiment, as described above, has such a structure as to include the FP portion in the gate electrode 50, the FET is referred to as the integrated FPFET.

A thickness of the insulating film 20 in each of the tapered portions 20a and 20b becomes thinner as a position in each of the tapered portions 20a and 20b is closer to the Schottky junction portion. That is to say, the thickness of the insulating film 20 becomes thinner toward the opening. Each of the tapered portions 20a and 20b is formed at an angle of 45 degrees with an upper surface of the active layer 12. This angle is preferably in a range of 30 to 60 degrees. If the angle of each of the tapered portions is smaller than 30 degrees, a parasitic capacity is increased, thereby reducing a linear gain. On the other hand, if the angle of each of the tapered portions is larger than 60 degrees, the effect of relaxing concentration of an electric field is reduced, thereby decreasing a breakdown voltage of the FPFET.

Next, a description will hereinafter be given with respect to experimental samples prepared for evaluation of characteristics of a two-terminal breakdown voltage between the gate electrode and the drain electrode. In the experimental sample according to this embodiment, a length of the FP portion, i.e., a length Lfp of the gate electrode 50 from an end of the Schottky junction portion on the drain electrode 40 side to an end of the gate electrode is 0.5 μm, and a length of the gate electrode 50 from an end of the Schottky junction portion on the source electrode 30 side to an end of the gate electrode is 0.2 μm. When a length from a recess end on the source electrode 30 side to the end of the Schottky junction portion between the gate electrode 50 and the active layer 12 is assigned Lgsr, and a length from the recess end on the drain electrode 40 side to the end of the Schottky junction portion is assigned Lgdr, Lgsr is 1.0 μm and Lgdr is 2.5 μm. In addition, a thickness of the insulating film 20 is 200 nm in an area except for the tapered portions 20a and 20b.

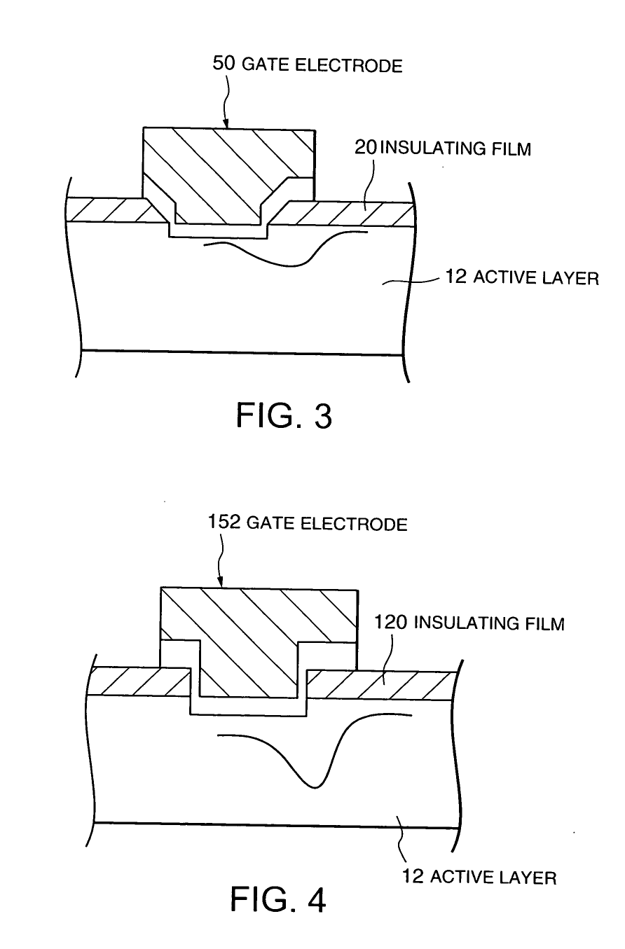

FIG. 3 is a schematic cross sectional view showing a structure of the experimental sample according to this embodiment having the above-mentioned structure. In FIG. 3, illustration of the structure of the source electrode, the drain electrode, and the like is omitted for the sake of simplicity. In addition, in the following description, a gate length as a length of the Schottky junction portion between the gate electrode 50 and the active layer 12 is designated with Lg, and a size in a direction intersecting perpendicularly a direction of the gate length Lg is referred to as “a gate width”.

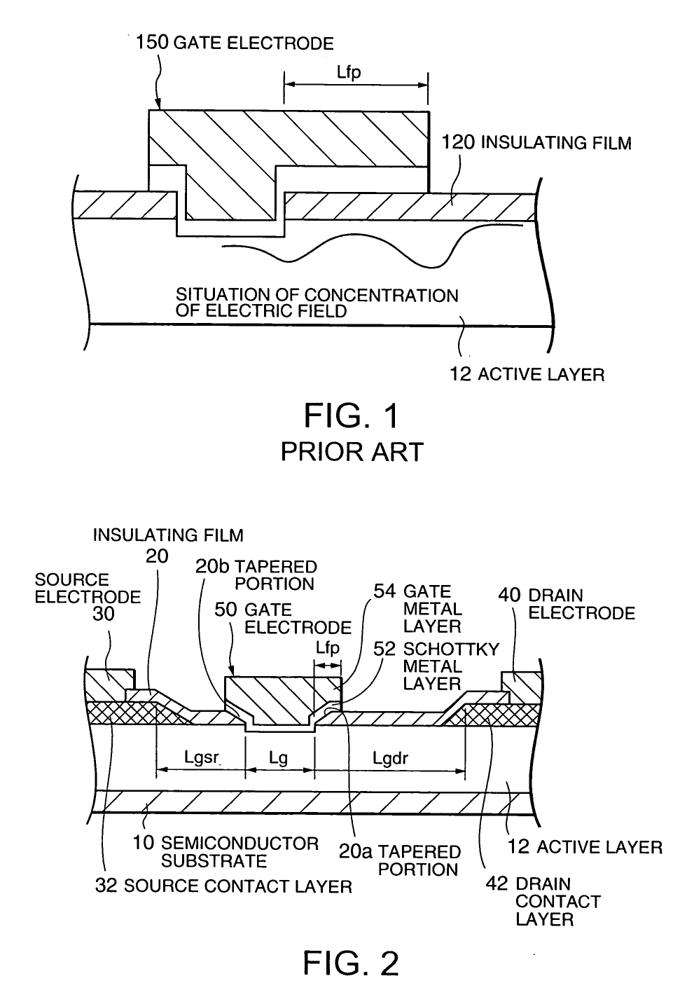

The conventional FPFET shown in FIG. 1 is assigned an experimental example B. In this case, Lfp is 1.0 μm. A length from the end of the Schottky junction portion on the source electrode 30 side to the end of the gate electrode is 0.2 μm, Lgsr is 1.0 μm, Lgdr is 2.5 μm, and the thickness of the insulating film 20 is 200 nm. Thus, these values are made the same as those in the experimental sample according to this embodiment.

FIG. 4 is a schematic cross sectional view showing a structure of an experimental sample A having a gate electrode in which Lfp is 0.5 μm and hence a length of an FP is made shorter than that in the conventional FPFET shown in FIG. 1.

Note that, FIGS. 1, 3 and 4 are schematic cross sectional views each useful in explaining a shape of a gate electrode, and a situation of an electric field intensity. In these figures, illustration of a structure of a source electrode, a drain electrode, and the like is omitted for the sake of simplicity. As shown in FIGS. 4 and 1, in each of the experimental samples A and B, a contact surface between the gate electrode 150 or 152 and the insulating film 120 is formed so as to be nearly perpendicular to the upper surface of the active layer 12.

Next, the results of the evaluation of the two-terminal breakdown voltage characteristics will hereinafter be described.

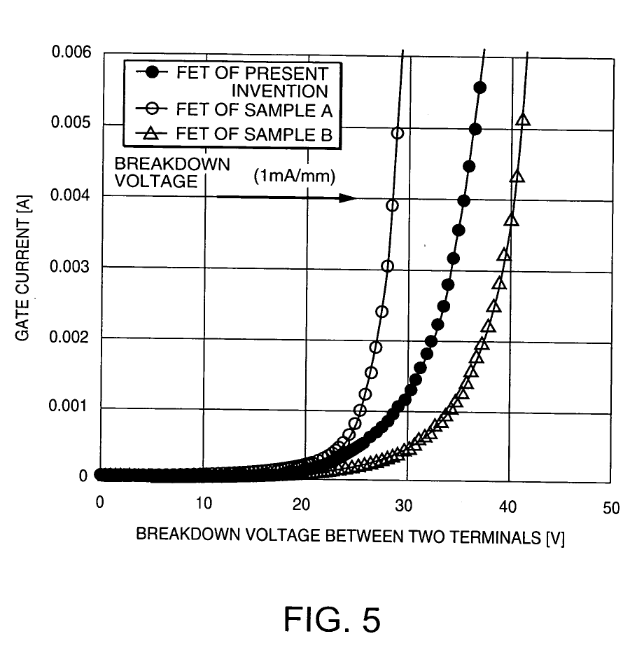

FIG. 5 is a graphical representation useful in explaining comparison in two-terminal breakdown voltage characteristics among the above-mentioned three experimental samples. In the figure, an axis of abscissa represents a value of a voltage applied to the gate electrode, and an axis of ordinate represents a gate current Ig caused to flow through the gate electrode and the drain electrode. A breakdown voltage is defined in the form of a voltage value when a gate current value Ig regulated on the basis of unit length of the gate width becomes 1 mA/mm.

As apparent from the graph shown in FIG. 5, a breakdown voltage of the FET of the experimental sample A was about 28 V, whereas a breakdown voltage value of the FET according to this embodiment was about 36 V, and a breakdown voltage of the FET of the experimental sample B was about 40 V. Thus, even in the FET according to this embodiment, the effect of improving a breakdown voltage as the feature of the FP was also recognized. As this cause, it is judged that as shown in FIG. 3, the provision of the tapered portions in the contact surface between the gate electrode and the insulating film relaxes the concentration of the electric field below the gate electrode.

The electric field intensities are schematically shown in FIGS. 3 and 4, respectively. A curve in each of these figures is obtained by plotting electric field intensities in respective horizontal positions against the down direction of the y-axis. As shown in FIG. 4, in case of the FET of the experimental sample A, since the electric field intensity at the end of the drain electrode side of the Schottky junction portion becomes very large, it is judged that the relaxation of the electric field intensity is insufficient. On the other hand, as shown in FIG. 3, in case of the FET according to this embodiment, since the electric field intensity is dispersed to the side of the drain electrode so that a maximum value of the electric field intensity is reduced as compared with the case of the FET of the experimental sample A shown in FIG. 4, it is judged that the electric field intensity is relaxed.

Next, RF characteristics of the above-mentioned three experimental samples will hereinafter be described.

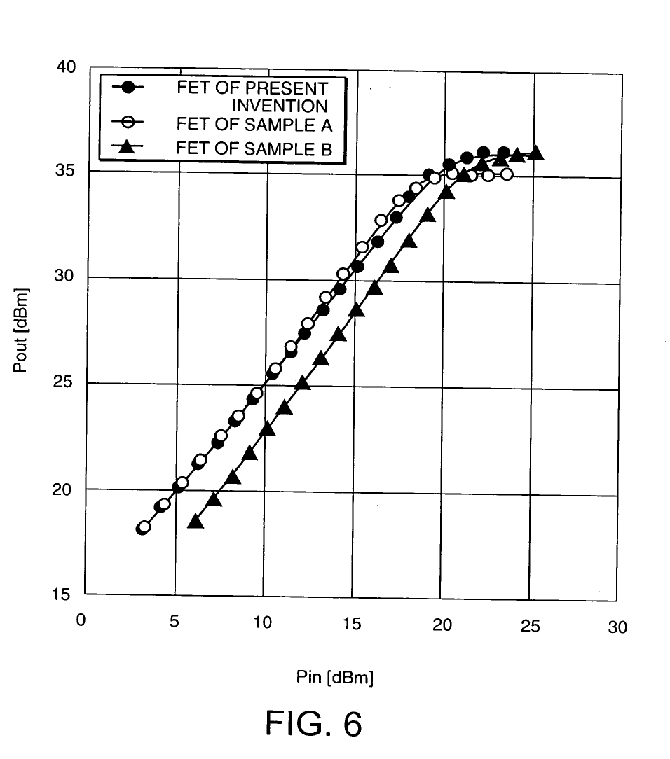

FIG. 6 is a graphical representation useful in explaining comparison in RF characteristics among the above-mentioned three experimental samples. In the figure, an axis of abscissa represents an input power, and an axis of ordinate represents an output power. Evaluation with respect to the RF characteristics was carried out under the conditions in which in the FET with 4 mm gate width, an operating voltage was 18 V, and a frequency was 1.5 GHz. For the purpose of bringing out the characteristics of the FET, gain matching is set on an input side, and power matching is set on an output side.

As shown in FIG. 6, when the input power becomes larger than 20 dBm, the value of the output power of the FET of the experimental sample A is saturated. On the other hand, although the output powers of the FETs of this embodiment and the experimental sample B are compressed a little, when the input power becomes larger than 20 dBm, their output powers still continue to be increased so that their output powers are improved by 1 dB as compared with the case of the FET of the experimental sample A. As a cause of the above, it is judged that in the FETs of the experimental sample B and this embodiment, the gate lag is suppressed as compared with the case of the FET of the experimental sample A.

On the other hand, when the output powers at the input power of 10 dBm in an area in which each of the output powers is linearly changed with respect to the input power as shown in FIG. 6 are compared with one another, the gain of the FET according to this embodiment is improved by 2 dB as compared with the case of the FET of the experimental sample B. As a cause of the above, it is judged that the shortening of the FP length in the FET according to this embodiment results in that a parasitic capacity is reduced to improve the gain.

From the above-mentioned results, in the FET according to this embodiment, concentration of the electric field on the gate edge during application of a voltage to the gate electrode is relaxed to improve the breakdown voltage. In addition, there is offered an effect that the parasitic capacity can be reduced to obtain the high gain.

Next, a method of manufacturing the FET having the above-mentioned structure will hereinafter be described. Note that, since a process for formation of the source electrode 30 and the drain electrode 40, a process for formation of a wiring, and the like are the same as those in a method of manufacturing a conventional FET, its detailed description is omitted here.

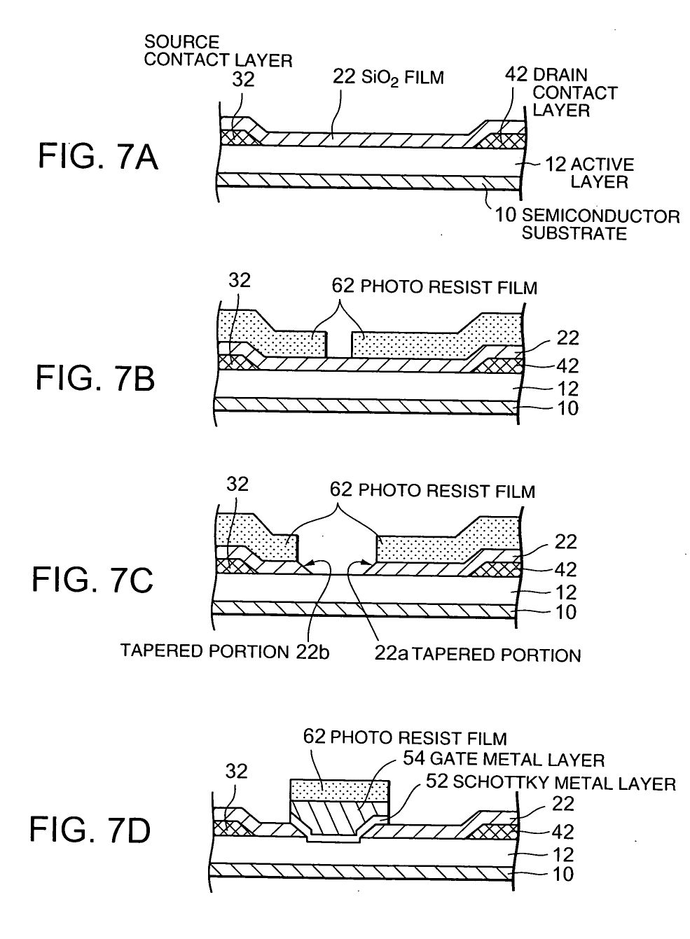

FIGS. 7A to 7D are cross sectional views useful in explaining a method of manufacturing the FET according to this embodiment.

As shown in FIG. 7A, the active layer 12 made of a GaAs semiconductor is grown on the semiconductor substrate 10, and a contact layer made of an n⁺ type GaAs semiconductor is formed on the active layer 42. A recess portion is then formed in the contact layer to form the source contact layer 32 and the drain contact layer 12. Thereafter, an oxide film (SiO₂ film) 22 is formed as the insulating film over the source contact layer 32, the drain contact layer 42, and the active layer 12.

Subsequently, a photo resist film 62 is formed so as to cover the SiO₂ film 22 except for a part corresponding to the opening through which the gate electrode 50 is to be contacted to the active layer 12 through a well known photolithography process (refer to FIG. 7B). Note that, under the consideration in which the photo resist film 62 will be spread by side etching in a subsequent etching process, it is necessary to previously design the opening of the mask pattern narrower than desired or to adjust exposure.

Thereafter, the SiO₂ film 22 is selectively etched away with the photo resist film 62 as a mask through the dry etching process to form the opening under the conditions in which an etching gas is SF₆, a pressure is set in a range of 0.5 to 0.9 mTorr, a microwave power is set in a range of 100 to 150 W, and an RF power is set in a range of 5 to 10 W using an ECR (Electron Cyclotron Resonance) plasma etching system. Since both the SiO₂ film 22 and the photo resist film 62 suffer the side etching through this dry etching process, with the progress of the etching for the SiO₂ film 22, a width of the opening of the photo resist film 62 is increased so that the tapered portions 22a and 22b each having an inclined etching shape in cross section are formed in the opening of the SiO₂ film 22 (refer to FIG. 7C). An inclination angle of each of the tapered portions 22a and 22b is determined on the basis of a side etching rate of the photo resist film 62 and an etching rate of the SiO₂ film 22. In this embodiment, since these etching rates were made equal to each other, the angle of each of the inclination portions became 45 degrees.

It should be noted that the processing conditions typified by a kind of photo resist film 62, a kind of gas in the dry etching processing, the pressure, the temperature, and the like are optimized to change the selective etching characteristics of the photo resist film 62 and the SiO₂ film 22, whereby the tapered portions can be formed so as to have an arbitrary inclination angle.

Subsequently, after removal of the photo resist film 62, a tungsten silicide (WSi) film is deposited as the Schottky metal 52, and a gold (Au) film is formed as a film for the gate electrode 54 over the tungsten silicide film. Then, after a photo resist film 64 is formed so as to cover a gate electrode portion including the FP through the photolithography process, the gate electrode 50 is formed through an ion milling processing (refer to FIG. 7D). Note that, the FP portion, as shown in FIG. 7D, is formed so as to cover the tapered portion 22a and also so as to reach a flat portion of the SiO₂ film 22.

Thereafter, similarly to the prior art, after openings are formed in parts of the SiO₂ film 22 overlying the source contact layer 32 and the drain contact layer 42, respectively, the source electrode 30 and the drain electrode 40 each made of an AuGeNi metal are formed so as to fill in the openings, respectively.

Note that, as for the gas used as the etching gas during the etching of the SiO₂ film 22 as the insulating film, a mixed gas containing a CF₄ gas and an oxygen gas (O₂) may be adopted instead of the SF₆ gas as described above. In this case, since the SiO₂ film 22 is mainly etched with the CF₄ gas, and the photo resist film 62 having the gate opening is mainly etched with the O₂ gas, each of the tapered portions can be formed so as to have an arbitrary inclination angle by adjusting a mixture ratio of the two gases.

Second Embodiment

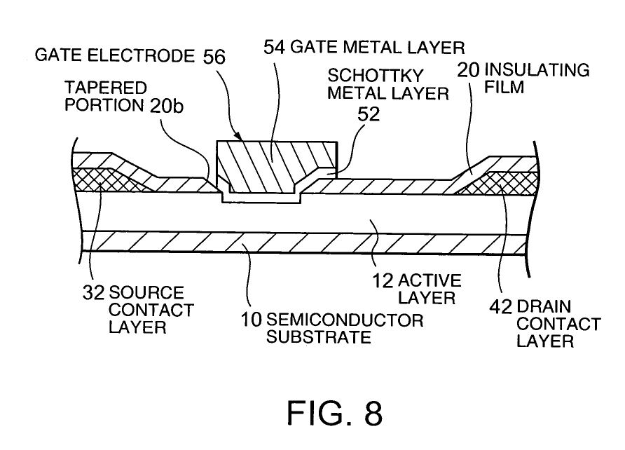

FIG. 8 is a cross sectional view showing a structure of an FET according to a second embodiment of the present invention. As shown in FIG. 8, in the FET of this embodiment, a portion of the gate electrode shown in the first embodiment on the side of the source electrode is short, and a side wall of the gate electrode 56 on the side of the source electrode is formed on the inclination portion 20b.

A gate electrode 56 of the FET of this embodiment is formed by adjusting a size of a mask for formation of the photo resist film 64 to remove parts of the Schottky metal 52 and the gate metal 54 on the tapered portion on the source electrode side through an ion milling process in FIG. 7D shown in the first embodiment.

In this embodiment, the part of the gate electrode on the source electrode side is shortened, whereby an unnecessary parasitic capacity on the source electrode side can be removed to improve the gain.

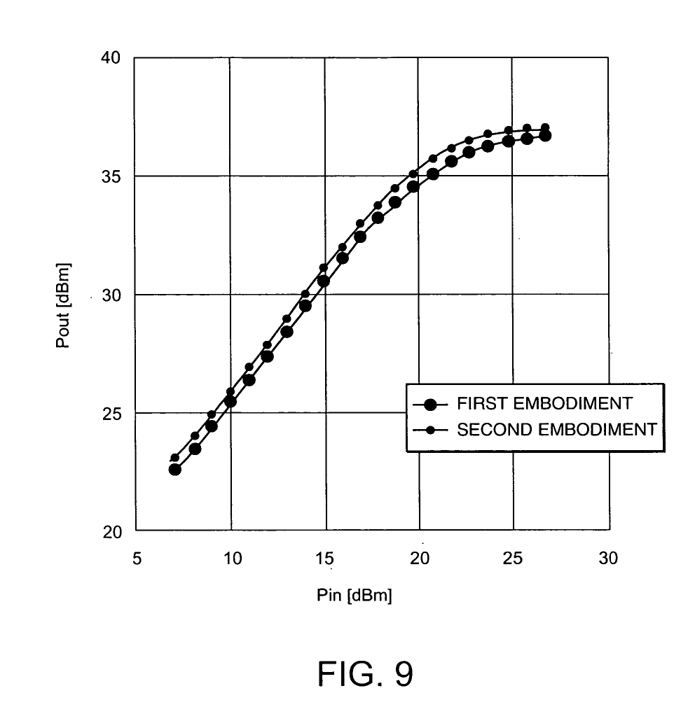

Graphs of RF input/output characteristics of the FETs of the above-mentioned first and second embodiments are shown in FIG. 9. In the figure, an axis of abscissa of the graphs represents an input power, and an axis of ordinate represents an output power.

As shown in FIG. 9, a linear gain of the FET of the second embodiment is improved by about 0.5 dB as compared with the case of the FET of the first embodiment.

It should be noted that in the first and second embodiments, a material of the insulating films 20, 23 and 24 is not intended to be limited to the above-mentioned SiO₂ film, and hence any other material such as an SiN film may also be adopted for such insulating films. While the thicknesses of the deposited insulating films 20 and 23 are not intended to be limited to 200 nm in the above-mentioned case, for enhancement of the effect specific to the FP, the thicknesses of such insulating films are preferably equal to or smaller than 300 nm.

What is claimed is:

1. A field effect transistor comprising: a drain electrode and a source electrode formed above a semiconductor active layer; an insulating film formed on said semiconductor active layer between said drain electrode and said source electrode; and a gate electrode formed in an opening of said insulating film formed between said drain electrode and said source electrode,
wherein a side wall of said opening of said insulating film where said gate electrode touches said insulating film, on a side of said drain electrode, includes an tapered portion formed so as to be inclined from a plane perpendicular to an upper surface of said semiconductor active layer toward said drain electrode.

2. The field effect transistor according to claim 1, wherein said side wall of the gate electrode, on the side of said drain electrode, includes said tapered portion formed so as to be inclined from the plane perpendicular to said upper surface of said semiconductor active layer toward said drain electrode, and said gate electrode has a shape spreading toward an upper portion.

3. The field effect transistor according to claim 1, wherein said tapered portion is inclined at an angle of 30 to 60 degrees with said upper surface of said semiconductor active layer.

4. A transistor comprising a channel layer, an insulating layer covering said channel layer, an opening selectively formed in said insulating layer to expose a part of said channel layer, and a gate electrode having a Schottky barrier junction with said part of said channel layer through said opening and elongated over said insulating layer, said opening having a tapered side wall that spreads upwardly from said channel layer.

5. The transistor as claimed in claim 4, wherein an angle of said tapered side wall is in a range of 30 to 60 degrees with respect to a surface of said channel layer.

6. The transistor as claimed in claim 4, wherein a recess is provided at said part of said channel layer, and said gate electrode is elongated over said insulating layer toward a drain electrode.

7. A method of manufacturing a field effect transistor having a gate electrode between a drain electrode and a source electrode formed above a semiconductor active layer, comprising:
forming an opening for exposure of a part of the semiconductor active layer in an insulating film formed between said drain electrode and said source electrode formed above said semiconductor active layer such that a sidewall of said opening, on a side of said drain electrode, includes a tapered portion formed so as to be inclined from a plane perpendicular to an upper surface of said semiconductor active layer to the side of said drain electrode; and
forming said gate electrode so as to cover at least said tapered portion and said upper surface of said semiconductor active layer in said opening.

8. The method of manufacturing a field effect transistor according to claim 7, wherein a photo resist film for formation of said opening is formed over said insulating film, and said insulating film is etched to form said opening under conditions of obtaining etching rates of said insulating film and said photo resist film allowing an angle of said tapered portion in said sidewall of said opening to be within a range of 30 to 60 degrees.

9. The method of manufacturing a field effect transistor according to claim 7, wherein a photo resist film for formation of said opening is formed over said insulating film, and said insulating film is etched to form said opening under conditions in which the etching rate of said insulating film is equal to the etching rate of said photo resist film.
